(19) United States
(12) Patent Application Publication
(10) Pub. No.: US 2014/0061584 A1
(43) Pub. Date: Mar. 6, 2014

(54) DEVICES AND METHODS

(71) Applicant: QD Vision, Inc., (US)

(72) Inventors: Gagan Mahan, Watertown, MA (US); Peter T. Kazlas, Sudbury, MA (US)

(73) Assignee: QD VISION, INC., Lexington, MA (US)

(21) Appl. No.: 13/683,365

(22) Filed: Nov. 21, 2012

Related U.S. Application Data
(63) Continuation of application No. PCT/US2011/037986, filed on May 25, 2011.
(60) Provisional application No. 61/348,067, filed on May 25, 2010.

(51) Int. Cl. H01L 33/64; H01L 31/024

(52) U.S. Cl. CPC H01L 33/641; H01L 31/024
USPC 257/13; 257/21

(57) ABSTRACT

A device comprising an arrangement of device materials and a layer comprising a material with heat-dissipating properties disposed over at least a portion thereof is disclosed. The device can further include an interleave layer disposed between the top surface of the arrangement of device materials and the layer comprising a material with heat-dissipating properties. A barrier layer may further be included between the arrangement of device materials and the layer comprising a material with heat-dissipating properties. Methods are also disclosed. In certain embodiments, a device includes quantum confined semiconductor nanoparticles.

This application is a continuation of commonly owned International Application No. PCT/US2011/037986 filed 25 May 2011, which was published in the English language as PCT Publication No. WO 2012/030421 on 8 Mar. 2012, which International Application claims priority to U.S. Application No. 61/348,067 filed 25 May 2010. Each of the foregoing is hereby incorporated herein by reference in its entirety.

### FEDERALLY SPONSORED RESEARCH OR DEVELOPMENT

This invention was made with Government support under Contract No. 2004*H838109*000 awarded by the Central Intelligence Agency. The Government has certain rights in the invention.

### TECHNICAL FIELD OF THE INVENTION

The present invention relates to the technical field of devices.

### SUMMARY OF THE INVENTION

In accordance with one aspect of the present invention, there is provided a device comprising an arrangement of device materials and a layer comprising a material with heat-dissipating properties disposed over at least a portion thereof.

A device can include a layer comprising a material with heat-dissipating properties disposed over any surface of the arrangement of device materials that is not covered by a material that isolates it from ambient atmosphere.

A device can include a substrate on which the device materials are arranged. In such case the layer comprising a material with heat-dissipating properties can be disposed over surfaces of the arrangement of device materials that are not covered by the substrate.

A device can include a layer comprising a material with heat-dissipating properties that fully encapsulates the outer surfaces of the device disposed over the substrate.

Optionally, the layer comprising a material with heat-dissipating properties can also be disposed over external surfaces of the substrate.

Any contacts for the device that may be located on the substrate surface adjacent the device are preferably not covered by the layer.

Optionally, a bead of sealant can be added around the perimeter edge of the encapsulating layer on the substrate to improve the seal.

A device can include a layer comprising material with heat-dissipating properties that covers at least the top surface of the underlying device and can further comprise an edge seal around any exposed sides of the device such that the edge seal and the material with heat-dissipating properties fully encapsulate the outer surfaces of the device disposed over the substrate.

A device can comprise a stacked arrangement of layers of device materials. Each layer can comprise one or more sublayers. Each layer or sublayer can comprise one or more device materials.

A device can include an electrode material as the uppermost material in the arrangement of device materials over which the layer comprising a material with heat-dissipating properties is disposed.

A material with heat-dissipating properties can comprise, for example, a non-metal.

A material with heat-dissipating properties can comprise, for example, an epoxy material.

A material with heat-dissipating properties can comprise, for example, an epoxy material which is white.

A material with heat-dissipating properties can comprise a material including a heat conductive filler.

A material with heat-dissipating properties can comprise, for example, a polymer, resin, or other host material including a heat conductive filler dispersed therein.

A material with heat-dissipating properties can comprise, for example, an epoxy material including a heat conductive filler dispersed therein.

In certain embodiments, a material with heat-dissipating properties is electrically insulating.

Other materials with heat-dissipating properties can be identified and used.

A heat conductive filler can comprise, for example, an oxide, a nitride, a titanate, or a mixture including any one or more of the foregoing.

A heat conductive filler can comprise, for example, aluminum oxide, magnesium oxide, silicon oxide, zinc oxide, titanium oxide, or a mixture including any one or more of the foregoing.

A heat conductive filler can comprise, for example, zirconium nitride, boron nitride, aluminum nitride, silicon nitride, or a mixture including any one or more of the foregoing.

A heat conductive filler can comprise, for example, barium titanate, barium strontium titanate, lead zirconium titanate, silicon, or a mixture including any one or more of the foregoing.

Other heat conductive fillers can be identified and used.

A layer comprising a material with heat-dissipating properties can have a thickness of for example, but not limited to 5 mm or less, 4 mm or less, 3 mm or less, 2 mm or less, 1 mm or less, 0.8 mm or less, 0.5 mm or less, 0.4 mm or less, 0.3 mm or less, 0.2 mm or less, 0.1 mm or less, 10 microns or less, 1 micron or less, 0.1 micron or less, 50 nm or less. Other thickness may also be determined to be desirable.

A device can further include an interleave layer disposed between the top surface of the arrangement of device materials and the layer comprising a material with heat-dissipating properties.

An interleave layer can isolate the device material at the top of the arrangement of device materials from the layer comprising the material with heat-dissipating properties.

An interleave layer can prevent lift-off or other disruption of the device material at the top of the arrangement of device materials by the layer comprising the material with heat-dissipating properties.

An interleave layer can comprise, for example, a material with a lower surface energy than that of the device material on which it is disposed.

An interleave layer can lower the surface energy at the top surface of the arrangement of device materials on which the layer comprising a material with heat-dissipating properties is to be formed.

An interleave layer can be a solid layer.

An interleave layer can be a gel.

An interleave layer can be a liquid.

An interleave layer can be a grease.

An interleave layer can be a paste.

An interleave layer can comprise, for example, graphite.

An interleave layer can comprise, for example, a graphite sheet.

An interleave layer can comprise, for example, a Teflon layer.

An interleave layer can comprise, for example, a metal foil layer (e.g., but not limited to, aluminum foil.)

An interleave layer can comprise, for example, an inorganic material.

An interleave layer can comprise, for example, an organic material.

An interleave layer can comprise, for example, an organic small molecule material.

An interleave layer can comprise, for example, spiro-2-NPB.

An interleave layer can have a thickness of, for example, but not limited to, 500 nm or less, 400 nm or less, 300 nm or less, 200 nm or less, 100 nm or less, 50 nm or less, 25 nm or less, 20 nm or less, 10 nm of less, 5 nm or less, etc. Other thickness may also be determined to be desirable.

An interleave layer can have a thickness of a monolayer of the material from which it is formed.

An interleave layer can be unpatterned.

An interleave layer can be patterned. A pattern can be regular or random.

A device can further include a barrier layer between at least the top surface of the arrangement of device materials and the layer comprising a material with heat-dissipating properties.

A barrier layer comprises a layer that inhibits, and preferably prevents, passage of at least oxygen and/or water moisture.

Preferably, the barrier layer inhibits, and preferably prevents, passage of at least both oxygen and water moisture.

A barrier layer can comprise one or more barrier layers

A barrier layer can preferably have a thickness <1 micron. A thickness less than or equal to 50 nm can be preferable. However, as the skilled artisan can appreciate, other thickness can be used taking into consideration other aspects of the device structure, materials, and layer or component sizes, thicknesses, etc.

Barrier layers are discussed further below.

A barrier layer preferably covers exposed surfaces of the arrangement of device layers.

A barrier layer is preferably included before an interleave layer is disposed over the top layer of the device layers (if included) and before inclusion of the layer comprising a material capable of dissipating heat over at least a portion of the underlying device.

A device taught herein can include an interleave layer and a barrier layer.

In certain embodiments, a layer can acts as both an interleave layer and a barrier layer.

In certain embodiments, an interleave layer and a barrier layer are separate layers.

In devices in which an interleave layer and a barrier layer comprise separate layers, the barrier layer is preferably interposed between the uppermost device layer and the interleave layer.

A device can be a multi-layer thin film device.

In accordance with another aspect of the present invention, there is provided a device comprising a substrate, a first electrode disposed over a predetermined region of a surface of the substrate, a second electrode disposed over the first electrode, and a layer comprising a material with heat-dissipating properties disposed over the second electrode.

A device can further include an interleave layer between the second electrode and the layer comprising a material with heat-dissipating properties.

An interleave layer can comprise an interleave layer as described above and elsewhere herein.

A material with heat-dissipating properties can comprise, for example, a non-metal.

A material with heat-dissipating properties can comprise, for example, an epoxy material.

A material with heat-dissipating properties can comprise, for example, an epoxy material which is white.

A material with heat-dissipating properties can comprise a material including a heat conductive filler.

A material with heat-dissipating properties can comprise, for example, a polymer, resin, or other host material including a heat conductive filler dispersed therein.

A material with heat-dissipating properties can comprise, for example, an epoxy material including a heat conductive filler dispersed therein.

In certain embodiments, a material with heat-dissipating properties is electrically insulating.

Other materials with heat-dissipating properties can be identified and used.

A heat conductive filler can comprise, for example, an oxide, a nitride, a titanate, or a mixture including any one or more of the foregoing.

A heat conductive filler can comprise, for example, aluminum oxide, magnesium oxide, silicon oxide, zinc oxide, titanium oxide, or a mixture including any one or more of the foregoing.

A heat conductive filler can comprise, for example, zirconium nitride, boron nitride, aluminum nitride, silicon nitride, or a mixture including any one or more of the foregoing.

A heat conductive filler can comprise, for example, barium titanate, barium strontium titanate, lead zirconium titanate, silicon, or a mixture including any one or more of the foregoing.

Other heat conductive fillers can be identified and used.

A layer comprising a material with heat-dissipating properties can have a thickness of for example, but not limited to, 5 mm or less, 4 mm or less, 3 mm or less, 2 mm or less, 1 mm or less, 0.8 mm or less, 0.5 mm or less, 0.4 mm or less, 0.3 mm or less, 0.2 mm or less, 0.1 mm or less, 10 microns or less, 1 micron or less, 0.1 micron or less, 50 nm or less. Other thickness may also be determined to be desirable.

A device can include a layer comprising material with heat-dissipating properties that covers at least the top surface of the underlying device.

A device can include a layer comprising a material with heat-dissipating properties that fully encapsulates the outer surfaces of the device disposed over the substrate.

Optionally, the layer comprising a material with heat-dissipating properties can also be disposed over external surfaces of the substrate.

Any contacts for the device that may be located on the substrate surface adjacent the device are preferably not covered by the layer.

Optionally, a bead of sealant can be added around the perimeter edge of the encapsulating layer on the substrate to improve the seal.

A device can include a layer comprising material with heat-dissipating properties that covers at least the top surface of the underlying device and can further comprise an edge seal around any exposed sides of the device such that the edge seal and the material with heat-dissipating properties fully encapsulate the outer surfaces of the device disposed over the substrate.

A device can comprise a stacked arrangement of layers of device materials. Each layer can comprise one or more sublayers. Each layer or sublayer can comprise one or more device materials.

A device can comprise a light-emitting device.

A device can include a layer comprising an organic electroluminescent material between the electrodes.

A device can comprise an organic light emitting device.

A device can include a layer comprising quantum confined semiconductor nanoparticles.

A device can include a layer comprising quantum confined semiconductor nanoparticles disposed between the electrodes.

A device can comprise a light-emitting device including an emissive material comprising quantum confined semiconductor nanoparticles.

A device can include a layer comprising nano-phosphors.

A device can include a layer comprising nano-phosphors disposed between the electrodes.

A device can comprise a photovoltaic device.

A device can comprise a photovoltaic device comprising a light-absorbing material comprising quantum confined semiconductor nanoparticles.

A device can further include additional layers and/or components.

In accordance with another aspect of the present invention, there is provided a device comprising a substrate, a first electrode disposed over a predetermined region of a surface of the substrate, an active layer disposed over the first electrode, wherein the active layer comprises nanoparticles having light-absorbing and/or light-emissive capabilities, a second electrode disposed over the emissive layer, and a layer comprising a material with heat-dissipating properties disposed over the second electrode.

A device can comprise nanoparticles comprising quantum-confined semiconductor nanoparticles.

A device can comprise a light-emissive nanoparticles comprising quantum-confined semiconductor nanoparticles.

A device can comprise a light-absorbing nanoparticles comprising quantum-confined semiconductor nanoparticles.

A device can comprise nanoparticles comprising nano-phosphor.

A device can further comprise an interleave layer between the second electrode and the layer comprising a material with heat-dissipating properties.

An interleave layer can comprise an interleave layer as described above and elsewhere herein.

A device can further include a barrier layer between the top surface of the arrangement of device materials and the layer comprising a material with heat-dissipating properties.

A barrier layer comprises a layer that inhibits, and preferably prevents, passage of at least oxygen and/or water moisture.

Preferably, the barrier layer inhibits, and preferably prevents, passage of at least both oxygen and water moisture.

A barrier layer can comprise a barrier layer as described above and elsewhere herein.

A barrier layer preferably covers exposed surfaces of the arrangement of device layers.

A barrier layer is preferably included before an interleave layer is disposed over the top layer of the device layers (if included) and before inclusion of the layer comprising a material capable of dissipating heat over at least a portion of the underlying device.

A device taught herein can include an interleave layer and a barrier layer.

In certain embodiments, a layer can acts as both an interleave layer and a barrier layer.

In certain embodiments, an interleave layer and a barrier layer are separate layers.

In devices in which an interleave layer and a barrier layer comprise separate layers, the barrier layer is preferably interposed between the uppermost device layer and the interleave layer.

A material with heat-dissipating properties can comprise, for example, a non-metal.

A material with heat-dissipating properties can comprise, for example, an epoxy material.

A material with heat-dissipating properties can comprise, for example, an epoxy material which is white.

A material with heat-dissipating properties can comprise a material including a heat conductive filler.

A material with heat-dissipating properties can comprise, for example, a polymer, resin, or other host material including a heat conductive filler dispersed therein.

A material with heat-dissipating properties can comprise, for example, an epoxy material including a heat conductive filler dispersed therein.

In certain embodiments, a material with heat-dissipating properties is electrically insulating.

Other materials with heat-dissipating properties can be identified and used.

A heat conductive filler can comprise, for example, an oxide, a nitride, a titanate, or a mixture including any one or more of the foregoing.

A heat conductive filler can comprise, for example, aluminum oxide, magnesium oxide, silicon oxide, zinc oxide, titanium oxide, or a mixture including any one or more of the foregoing.

A heat conductive filler can comprise, for example, zirconium nitride, boron nitride, aluminum nitride, silicon nitride, or a mixture including any one or more of the foregoing.

A heat conductive filler can comprise, for example, barium titanate, barium strontium titanate, lead zirconium titanate, silicon, or a mixture including any one or more of the foregoing.

Other heat conductive fillers can be identified and used.

A layer comprising a material with heat-dissipating properties can have a thickness of, for example, but not limited to, 5 mm or less, 4 mm or less, 3 mm or less, 2 mm or less, 1 mm or less, 0.8 mm or less, 0.5 mm or less, 0.4 mm or less, 0.3 mm or less, 0.2 mm or less, 0.1 mm or less, 10 microns or less, 1 micron or less, 0.1 micron or less, 50 nm or less. Other thickness may also be determined to be desirable.

A device can include a layer comprising material with heat-dissipating properties that covers at least the top surface of the underlying device.

A device can include a layer comprising a material with heat-dissipating properties that fully encapsulates the outer surfaces of the device disposed over the substrate.

Optionally, the layer comprising a material with heat-dissipating properties can also be disposed over external surfaces of the substrate.

Any contacts for the device that may be located on the substrate surface adjacent the device are preferably not covered by the layer.

Optionally, a bead of sealant can be added around the perimeter edge of the encapsulating layer on the substrate to improve the seal.

A device can include a layer comprising material with heat-dissipating properties that covers at least the top surface of the underlying device and can further comprise an edge seal around any exposed sides of the device such that the edge seal and the material with heat-dissipating properties fully encapsulate the outer surfaces of the device disposed over the substrate.

A device can comprise a light-emitting device and the nanoparticles can comprise nanoparticles having light-emissive capabilities.

A device can comprise a photovoltaic device.

In accordance with another aspect of the present invention, there is provided a display comprising one or more light-emitting devices taught herein.

In accordance with another aspect of the present invention, there is provided a method for improving the performance of a device, the method comprising providing a layer comprising a material with heat-dissipating properties over an external surface of at least one electrode of the device.

A material with heat-dissipating properties can comprise a material with heat-dissipating properties described above and elsewhere herein.

A layer comprising a material with heat-dissipating properties can be formed at a thickness of, for example, but not limited to, 5 mm or less, 4 mm or less, 3 mm or less, 2 mm or less, 1 mm or less, 0.8 mm or less, 0.5 mm or less, 0.4 mm or less, 0.3 mm or less, 0.2 mm or less, 0.1 mm or less, 10 microns or less, 1 micron or less, 0.1 micron or less, 50 nm or less. Other thickness may also be determined to be desirable.

A method can comprise providing a layer comprising a material with heat-dissipating properties over uncovered surfaces of an arrangement of device materials to encapsulate the underlying arrangement from ambient atmosphere.

The method can further comprise including an interleave layer over an external surface of at least one electrode of the device prior to providing the layer comprising a material with heat-dissipating properties thereover.

An interleave layer can comprise an interleave layer as described above and elsewhere herein.

The method can further comprise including a barrier layer over exposed surfaces of the arrangement of device layers before an interleave layer is disposed over the top layer of the device layers (if included) and before inclusion of the layer comprising a material capable of dissipating heat over at least a portion of the underlying device.

A barrier layer comprises a layer that inhibits, and preferably prevents, passage of at least oxygen and/or water moisture.

Preferably, the barrier layer inhibits, and preferably prevents, passage of at least both oxygen and water moisture.

A barrier layer can comprise a barrier layer as described above and elsewhere herein.

A barrier layer can comprise one or more barrier layers.

A barrier layer preferably covers exposed surfaces of the arrangement of device layers.

A barrier layer is preferably included before an interleave layer is disposed over the top layer of the device layers (if included) and before inclusion of the layer comprising a material capable of dissipating heat over at least a portion of the underlying device.

A method can further comprise including an interleave layer and a barrier layer.

In certain embodiments, a layer can acts as both an interleave layer and a barrier layer.

In certain embodiments, an interleave layer and a barrier layer are separate layers.

In methods which include providing an interleave layer and a barrier layer as separate layers, the barrier layer is preferably included so as to be between a top layer of the arrangement of device layers and the interleave layer.

In accordance with another aspect of the present invention, there is provided a method for improving the performance of a device, the method comprising providing an interleave layer over an external surface of at least one electrode of the device, and providing a layer comprising with heat-dissipating properties over the interleave layer.

An interleave layer can comprise an interleave layer described above and elsewhere herein.

An interleave layer can be formed at a thickness, for example, but not limited to, of 500 nm or less, of 400 nm or less, of 300 nm or less, of 200 nm or less, of 100 nm or less, of 50 nm or less, or 25 nm or less, of 20 nm or less, of 10 nm of less, of 5 nm or less, etc. Other thickness may also be determined to be desirable.

An interleave layer can be formed at a thickness of a monolayer of the material from which it is formed.

An interleave layer can be formed as an unpatterned layer.

An interleave layer can be formed as a patterned layer. A pattern can be regular or random.

A material with heat-dissipating properties can comprise a material with heat-dissipating properties described above and elsewhere herein.

A layer comprising a material with heat-dissipating properties can be formed at a thickness of, for example, but not limited to, 5 mm or less, 4 mm or less, 3 mm or less, 2 mm or less, 1 mm or less, 0.8 mm or less, 0.5 mm or less, 0.4 mm or less, 0.3 mm or less, 0.2 mm or less, 0.1 mm or less, 10 microns or less, 1 micron or less, 0.1 micron or less, 50 nm or less. Other thickness may also be determined to be desirable.

A method can comprise providing a layer comprising a material with heat-dissipating properties over uncovered surfaces of an arrangement of device materials to encapsulate the underlying arrangement from ambient atmosphere.

Optionally, the method further comprises forming a barrier layer over exposed surfaces of the device before the interleave layer is provided.

A barrier layer comprises a layer that inhibits, and preferably prevents, passage of at least oxygen and/or water moisture.

Preferably, the barrier layer inhibits, and preferably prevents, passage of at least both oxygen and water moisture.

A barrier layer can comprise a barrier layer as described above and elsewhere herein.

A barrier layer can comprise one or more barrier layers.

A barrier layer preferably covers exposed surfaces of the arrangement of device layers.

A barrier layer can preferably have a thickness <1 micron. A thickness less than or equal to 50 nm can be preferable. However, as the skilled artisan can appreciate, other thickness can be used taking into consideration other aspects of the device structure, materials, and layer or component sizes, thicknesses, etc.

Examples of materials for inclusion a barrier layer include, but are not limited to, a polymer with oxygen and/or water barrier properties, metal oxide, glass, ceramic, alumina. Such layers can be formed by known techniques. As the skilled artisan will appreciate, other materials with oxygen and/or moisture barrier properties can be identified for inclusion in a barrier layer.

A barrier layer preferably covers exposed surfaces of the arrangement of device layers.

In certain embodiments, a layer can acts as both an interleave layer and a barrier layer.

In certain embodiments, an interleave layer and a barrier layer are separate layers.

The foregoing, and other aspects and embodiments described herein all constitute embodiments of the present invention.

It should be appreciated by those persons having ordinary skill in the art(s) to which the present invention relates that any of the features described herein in respect of any particular aspect and/or embodiment of the present invention can be combined with one or more of any of the other features of any other aspects and/or embodiments of the present invention described herein, with modifications as appropriate to ensure compatibility of the combinations. Such combinations are considered to be part of the present invention contemplated by this disclosure.

It is to be understood that both the foregoing general description and the following detailed description are exemplary and explanatory only and are not restrictive of the invention as claimed. Other embodiments will be apparent to those skilled in the art from consideration of the specification and practice of the invention disclosed herein.

### BRIEF DESCRIPTION OF THE DRAWINGS

In the drawings,

FIG. 1 schematically depicts an example of an embodiment of a device in accordance with one aspect of the present invention in cross-section.

FIG. 2 schematically depicts an example of an embodiment of a device in accordance with one aspect of the present invention in cross-section.

FIG. 3 schematically depicts an example of an embodiment of a device in accordance with one aspect of the present invention in cross-section.

The attached figures are simplified representations presented for purposes of illustration only; actual structures may differ in numerous respects, particularly including the relative scale of the articles depicted and aspects thereof.

For a better understanding to the present invention, together with other advantages and capabilities thereof, reference is made to the following disclosure and appended claims in connection with the above-described drawings.

### DETAILED DESCRIPTION OF THE INVENTION

Various aspects and embodiments of the present inventions will be further described in the following detailed description.

In accordance with one aspect of the present invention there is provided a device comprising an arrangement of device materials and a layer comprising a material with heat-dissipating properties disposed over at least a portion thereof.

Inclusion of a layer comprising a material with heat-dissipating properties disposed over at least a portion of the external device surface can provide a thermally conductive path for heat from the device. Such layer may further provide environmental protection and/or improved mechanical integrity of the device.

A device can include a layer comprising a material with heat-dissipating properties disposed over any surface of the arrangement of device materials that is not covered by a material that can isolate it from ambient atmosphere.

A device can include a substrate on which the device materials are arranged. In such case the layer comprising a material with heat-dissipating properties can be disposed over surfaces of the arrangement of device materials that are not covered by the substrate.

A device can include a layer comprising a material with heat-dissipating properties that fully encapsulates the outer surfaces of the device disposed over the substrate.

Optionally, the layer comprising a material with heat-dissipating properties can also be disposed over external surfaces of the substrate.

Any contacts for the device that may be located on the substrate surface adjacent the device are preferably not covered by the layer.

Optionally, a bead of sealant can be added around the perimeter edge of the encapsulating layer on the substrate to improve the seal.

A device can include a layer comprising material with heat-dissipating properties that covers at least the top surface of the underlying device and can further comprise an edge seal around any exposed sides of the device such that the edge seal and the material with heat-dissipating properties fully encapsulate the outer surfaces of the device disposed over the substrate.

A device can comprise a stacked arrangement of layers of device materials. Each layer can comprise one or more sublayers. Each layer or sublayer can comprise one or more device materials.

A device can include an electrode as the uppermost device material in the arrangement of device materials over which the layer comprising a material with heat-dissipating properties is disposed.

The layer comprising a material with heat-dissipating properties can cover all surfaces of the top electrode external to the device arrangement.

In certain embodiments, a device layer other than an electrode can comprise the uppermost layer of an arrangement of device materials.

The layer can cover all external surfaces of the device arrangement.

A material with heat-dissipating properties can comprise, for example, a non-metal.

A material with heat-dissipating properties can comprise, for example, a thermally conductive epoxy material.

A material with heat-dissipating properties can comprise, for example, a thermally conductive epoxy material which is white.

A material with heat-dissipating properties can comprise, for example, a thermally conductive epoxy material with light diffusing properties.

A material with heat-dissipating properties can comprise a material including a heat conductive filler. In such embodiments, the material in which the heat conductive filler is included may or may not possess heat-dissipating properties independent of the heat conductive filler. A material in which the heat conductive filler can be included can be readily identified by the skilled artisan.

A material with heat-dissipating properties can comprise, for example, a polymer, resin, or other host material including a heat conductive filler dispersed therein. Such polymers, resins, and other host materials can be readily identified by the skilled artisan.

A material with heat-dissipating properties can comprise, for example, an epoxy material including a heat conductive filler dispersed therein.

In certain embodiments, a material with heat-dissipating properties is electrically insulating.

Other materials with heat-dissipating properties can be identified and used.

A heat conductive filler can comprise, for example, an oxide, a nitride, a titanate, or a mixture including any one or more of the foregoing.

A heat conductive filler can comprise, for example, aluminum oxide, magnesium oxide, silicon oxide, zinc oxide, titanium oxide, or a mixture including any one or more of the foregoing.

A heat conductive filler can comprise, for example, zirconium nitride, boron nitride, aluminum nitride, silicon nitride, or a mixture including any one or more of the foregoing.

A heat conductive filler can comprise, for example, barium titanate, barium strontium titanate, lead zirconium titanate, silicon, or a mixture including any one or more of the foregoing.

Other heat conductive fillers can be identified and used.

A layer comprising a material with heat-dissipating properties can have a thickness of, for example, but not limited to, 5 mm or less, 4 mm or less, 3 mm or less, 2 mm or less, 1 mm or less, 0.8 mm or less, 0.5 mm or less, 0.4 mm or less, 0.3 mm or less, 0.2 mm or less, 0.1 mm or less, 10 microns or less, 1 micron or less, 0.1 micron or less, 50 nm or less. Other thickness may also be determined to be desirable.

Optionally, a layer comprising a material with heat dissipating properties included in the inventions described herein, can include one or more patterned or textured outer surfaces to provide a larger external surface area. Such increased external surface area can provide better convective cooling.

In certain embodiments, the layer comprising a material with heat dissipating properties comprises a material with a Young's modulus less than or equal to about 5 GPa, preferably less than or equal to about 1 GPa, more preferably 0.5 GPa or less.

In certain embodiments of the inventions described herein, a heat sink component can be further attached to the device after disposition of the layer comprising a material with heat dissipating properties. Such heat sink attachment can be attached thereto by a thermally conductive adhesive or gel or other known techniques.

A device can further include an interleave layer disposed between the top surface of the arrangement of device materials and the layer comprising a material with heat-dissipating properties.

An interleave layer can isolate the device material at the top of the arrangement of device materials from the layer comprising the material with heat-dissipating properties.

An interleave layer can prevent lift-off or other disruption of the device material at the top of the arrangement of device materials by the layer comprising the material with heat-dissipating properties.

An interleave layer can comprise, for example, a low surface energy material.

An interleave layer can comprise, for example, a material with a lower surface energy than that of the device material on which it is disposed.

An interleave layer can lower the surface energy at the top surface of the arrangement of device materials on which the layer comprising a material with heat-dissipating properties is formed.

An interleave layer can comprise a non-stick material.

An interleave layer can be a solid layer.

An interleave layer can be a gel.

An interleave layer can be a liquid.

An interleave layer can be a grease.

An interleave layer can be a paste.

An interleave layer can comprise, for example, graphite.

An interleave layer can comprise, for example, a graphite sheet.

An interleave layer can comprise, for example, a Teflon layer.

An interleave layer can comprise, for example, a metal foil layer (e.g., but not limited to, aluminum foil.)

An interleave layer can comprise, for example, an inorganic material.

An interleave layer can comprise, for example, an organic material.

An interleave layer can comprise, for example, a fluorocarbon material.

An interleave layer can comprise, for example, an organic small molecule material.

Am interleave layer can comprise, for example, spiro-2-NPB.

An interleave layer can have a thickness of, for example, but not limited to, 500 nm or less, 400 nm or less, 300 nm or less, 200 nm or less, 100 nm or less, 50 nm or less, 25 nm or less, 20 nm or less, 10 nm of less, 5 nm or less, etc. Other thickness may also be determined to be desirable.

An interleave layer can have the thickness of a monolayer of the material from which it is formed.

An interleave layer can comprise a self-assembled monolayer (SAM).

An interleave layer can be solution coated, vapor deposited, or formed by other techniques that can be readily ascertained by the skilled artisan.

An interleave layer can be unpatterned.

An interleave layer can be patterned. A pattern can be regular or random.

In certain embodiments, an interleave layer can provide a means of reducing the thermal resistance between a thermally conductive layer comprising a material with heat-dissipating properties and a thin-film device over which it is disposed without harming the thin films of the device which can comprise soft, delicate films (e.g., films or layers comprising quantum confined semiconductor nanocrystals, organic layers, or soft metal layers (e.g., aluminum, gold, etc.)

A device can further include a barrier layer between at least the top surface of the arrangement of device materials and the layer comprising a material with heat-dissipating properties.

A barrier layer comprises a layer that inhibits, and preferably prevents, passage of at least oxygen and/or water moisture.

Preferably, the barrier layer inhibits, and preferably prevents, passage of at least both oxygen and water moisture.

A barrier layer can comprise one or more barrier layers.

When multiple barrier layers are used, each layer does not have to be the same.

A variety of barrier materials can be employed. In certain embodiments, a barrier layer comprising an inorganic barrier material can be preferred. Examples of inorganic barrier materials include metal oxides, metal nitrides, metal carbides, metal oxynitrides, metal oxyborides, and combinations thereof, e.g., silicon oxides such as silica, aluminum oxides such as alumina, titanium oxides such as titania, indium oxides, tin oxides, indium tin oxide (“ITO”), tantalum oxide, zirconium oxide, niobium oxide, boron carbide, tungsten carbide, silicon carbide, aluminum nitride, silicon nitride, boron nitride, aluminum oxynitride, silicon oxynitride, boron oxynitride, zirconium oxyboride, titanium oxyboride, and combinations thereof. Indium tin oxide, silicon oxide, aluminum oxide and combinations thereof can be especially preferred inorganic barrier materials.

In certain embodiments, a barrier layer electrically insulating.

Barrier layers comprising inorganic barrier materials can be formed by known techniques such as sputtering, evaporation, chemical vapor deposition, plating, and the like. Alternatively, they can be formed atomic layer deposition, which can help to seal pin holes in the barrier coatings.

Other examples of barrier materials that can be included in a barrier layer include, but are not limited to, polymers with oxygen and/or water barrier properties, glass, and ceramics. Layers of such materials can be formed by known techniques.

As the skilled artisan will appreciate, other materials with oxygen and/or moisture barrier properties can be identified for inclusion in a barrier layer.

A barrier layer can preferably have a thickness <1 micron. A thickness less than or equal to 50 nm can be preferable. However, as the skilled artisan can appreciate, other thickness can be used taking into consideration other aspects of the device structure, materials, and layer or component sizes, thicknesses, etc.

A barrier layer preferably covers exposed surfaces of the device layers.

A barrier layer is preferably included before an interleave layer is disposed over the top layer of the device layers (if included) and before inclusion of the layer comprising a material capable of dissipating heat over at least a portion of the underlying device.

A device taught herein can include an interleave layer and a barrier layer.

In certain embodiments, a layer can acts as both an interleave layer and a barrier layer.

In certain embodiments, an interleave layer and a barrier layer are separate layers.

In devices in which an interleave layer and a barrier layer comprise separate layers, the barrier layer is preferably interposed between the uppermost device layer and the interleave layer.

A device can further include additional layers and/or components.

A device can be a multi-layer thin film device.

In accordance with another aspect of the present invention, there is provided a device comprising a substrate, a first electrode disposed over the substrate, a second electrode disposed over the first electrode, and a layer comprising a material with heat-dissipating properties disposed over the second electrode.

A device can comprise a stacked arrangement of layers of device materials. Each layer can comprise one or more sublayers. Each layer or sublayer can comprise one or more device materials.

A device can include the second electrode as the uppermost material in the arrangement of device materials over which the layer comprising a material with heat-dissipating properties is disposed.

A device can further include an interleave layer between the second electrode and the layer comprising a material with heat-dissipating properties.

An interleave layer can isolate the upper-most device material from the layer comprising the material with heat-dissipating properties.

An interleave layer can prevent lift-off or other disruption of the upper-most device material by the layer comprising the material with heat-dissipating properties.

An interleave layer can comprise, for example, a low surface energy layer.

An interleave layer can comprise, for example, a material with a lower surface energy than that of the device material on which it is disposed.

An interleave layer can lower the surface energy at the top surface of the arrangement of device materials on which the layer comprising a material with heat-dissipating properties is to be formed.

An interleave layer can be a solid layer.

An interleave layer can be a gel.

An interleave layer can be a liquid.

An interleave layer can be a grease.

An interleave layer can be a paste.

An interleave layer can comprise, for example, graphite.

An interleave layer can comprise, for example, a graphite sheet.

An interleave layer can comprise, for example, a Teflon layer.

An interleave layer can comprise, for example, a metal foil layer (e.g., but not limited to, aluminum foil.)

An interleave layer can comprise, for example, an inorganic material.

An interleave layer can comprise, for example, an organic material.

An interleave layer can comprise, for example, an organic small molecule material.

Am interleave layer can comprise, for example, spiro-2-NPB.

An interleave layer can have a thickness of, for example, but not limited to, 500 nm or less, 400 nm or less, 300 nm or less, 200 nm or less, 100 nm or less, 50 nm or less, 25 nm or less, 20 nm or less, 10 nm of less, 5 nm or less, etc. Other thickness may also be determined to be desirable.

An interleave layer can have a thickness of a monolayer of the material from which it is formed.

An interleave layer can be unpatterned.

An interleave layer can be patterned. A pattern can be regular or random.

A device can further include a barrier layer between the top surface of the arrangement of device materials and the layer comprising a material with heat-dissipating properties.

A barrier layer comprises a layer that inhibits, and preferably prevents, passage of at least oxygen and/or water moisture.

Preferably, the barrier layer inhibits, and preferably prevents, passage of at least both oxygen and water moisture.

A barrier layer can comprise a barrier layer as described above and elsewhere herein.

A barrier layer preferably covers exposed surfaces of the arrangement of device layers.

A barrier layer is preferably included before an interleave layer is disposed over the top layer of the device layers (if included) and before inclusion of the layer comprising a material capable of dissipating heat over at least a portion of the underlying device.

A device taught herein can include an interleave layer and a barrier layer.

In certain embodiments, a layer can acts as both an interleave layer and a barrier layer.

In certain embodiments, an interleave layer and a barrier layer are separate layers.

In devices in which an interleave layer and a barrier layer comprise separate layers, the barrier layer is preferably interposed between the uppermost device layer and the interleave layer.

A material with heat-dissipating properties can comprise, for example, a non-metal.

A material with heat-dissipating properties can comprise, for example, a thermally conductive epoxy material.

A material with heat-dissipating properties can comprise, for example, a thermally conductive epoxy material which is white.

A material with heat-dissipating properties can comprise a material including a heat conductive filler. In such embodiments, the material in which the heat conductive filler is included may or may not possess heat-dissipating properties independent of the heat conductive filler. A material in which the heat conductive filler can be included can be readily identified by the skilled artisan.

A material with heat-dissipating properties can comprise, for example, a polymer, resin, or other host material including a heat conductive filler dispersed therein. Such polymers, resins, and other host materials can be readily identified by the skilled artisan.

A material with heat-dissipating properties can comprise, for example, an epoxy material including a heat conductive filler dispersed therein.

In certain embodiments, a material with heat-dissipating properties is electrically insulating.

Other materials with heat-dissipating properties can be identified and used.

A heat conductive filler can comprise, for example, an oxide, a nitride, a titanate, or a mixture including any one or more of the foregoing.

A heat conductive filler can comprise, for example, aluminum oxide, magnesium oxide, silicon oxide, zinc oxide, titanium oxide, or a mixture including any one or more of the foregoing.

A heat conductive filler can comprise, for example, zirconium nitride, boron nitride, aluminum nitride, silicon nitride, or a mixture including any one or more of the foregoing.

A heat conductive filler can comprise, for example, barium titanate, barium strontium titanate, lead zirconium titanate, silicon, or a mixture including any one or more of the foregoing.

Other heat conductive fillers can be identified and used.

A layer comprising a material with heat-dissipating properties can have a thickness of, for example, but not limited to, 5 mm or less, 4 mm or less, 3 mm or less, 2 mm or less, 1 mm or less, 0.8 mm or less, 0.5 mm or less, 0.4 mm or less, 0.3 mm or less, 0.2 mm or less, 0.1 mm or less, 10 microns or less, 1 micron or less, 0.1 micron or less, 50 nm or less. Other thickness may also be determined to be desirable.

A device can include a layer comprising material with heat-dissipating properties that covers at least the top surface of the underlying device.

A device can include a layer comprising material with heat-dissipating properties that covers at least the top surface of the underlying device and can further comprise an edge seal around any exposed sides of the device such that the edge seal and the material with heat-dissipating properties fully encapsulate the outer surfaces of the device disposed over the substrate.

A device can include a layer comprising a material with heat-dissipating properties that fully encapsulates the outer surfaces of the device disposed over the substrate.

Optionally, the layer comprising a material with heat-dissipating properties can also be disposed over external surfaces of the substrate.

Any contacts for the device that may be located on the substrate surface adjacent the device are preferably not covered by the layer.

Optionally, a bead of sealant can be added around the perimeter edge of the encapsulating layer on the substrate to improve the seal.

A device can further include a layer comprising an organic electroluminescent material between the electrodes.

A device can comprise an organic light emitting device.

A device can include a layer comprising quantum confined semiconductor nanoparticles disposed between the electrodes.

A device can include a layer comprising nano-phosphors disposed between the electrodes.

A device can comprise a light-emitting device.

A device can comprise a photovoltaic device.

A device can further include additional layers and/or components.

In accordance with another aspect of the present invention, there is provided a device comprising a substrate, a first electrode disposed over a predetermined region of a surface of the substrate, an active layer disposed over the first electrode, wherein the active layer comprises nanoparticles having light-absorbing and/or light-emissive capabilities, a second electrode disposed over the emissive layer, and a layer comprising a material with heat-dissipating properties disposed over the second electrode.

A device can comprise nanoparticles comprising quantum-confined semiconductor nanoparticles.

A device can comprise nanoparticles comprising nano-phosphor.

A device can further comprise an interleave layer between the second electrode and the layer comprising a material with heat-dissipating properties.

An interleave layer can isolate the upper-most device material from the layer comprising the material with heat-dissipating properties.

An interleave layer can prevent lift-off or other disruption of the upper-most device material by the layer comprising the material with heat-dissipating properties.

An interleave layer can comprise, for example, a low surface energy layer.

An interleave layer can comprise, for example, a material with a lower surface energy than that of the device material on which it is disposed.

An interleave layer can lower the surface energy at the top surface of the arrangement of device materials on which the layer comprising a material with heat-dissipating properties is to be formed.

An interleave layer can be a solid layer.

An interleave layer can be a gel.

An interleave layer can be a liquid.

An interleave layer can be a grease.

An interleave layer can be a paste.

An interleave layer can comprise, for example, graphite.

An interleave layer can comprise, for example, a graphite sheet.

An interleave layer can comprise, for example, a Teflon layer.

An interleave layer can comprise, for example, a metal foil layer (e.g., but not limited to, aluminum foil.)

An interleave layer can comprise, for example, an organic compound.

An interleave layer can comprise, for example, an organic small molecule material.

Am interleave layer can comprise, for example, spiro-2-NPB.

An interleave layer can have a thickness of, for example, but not limited to, 500 nm or less, 400 nm or less, 300 nm or less, 200 nm or less, 100 nm or less, 50 nm or less, 25 nm or less, 20 nm or less, 10 nm of less, 5 nm or less, etc. Other thickness may also be determined to be desirable.

An interleave layer can have a thickness of a monolayer of the material from which it is formed.

An interleave layer can be unpatterned.

An interleave layer can be patterned. A pattern can be regular or random.

A device can further include a barrier layer between the top surface of the arrangement of device materials and the layer comprising a material with heat-dissipating properties.

A barrier layer comprises a layer that inhibits, and preferably prevents, passage of at least oxygen and/or water moisture.

Preferably, the barrier layer inhibits, and preferably prevents, passage of at least both oxygen and water moisture.

A barrier layer can comprise a barrier layer as described above and elsewhere herein.

A barrier layer preferably covers exposed surfaces of the arrangement of device layers.

A barrier layer is preferably included before an interleave layer is disposed over the top layer of the device layers (if included) and before inclusion of the layer comprising a material capable of dissipating heat over at least a portion of the underlying device.

A device taught herein can include an interleave layer and a barrier layer.

In certain embodiments, a layer can acts as both an interleave layer and a barrier layer.

In certain embodiments, an interleave layer and a barrier layer are separate layers.

In devices in which an interleave layer and a barrier layer comprise separate layers, the barrier layer is preferably interposed between the uppermost device layer and the interleave layer.

A material with heat-dissipating properties can comprise, for example, a non-metal.

A material with heat-dissipating properties can comprise, for example, a thermally conductive epoxy material.

A material with heat-dissipating properties can comprise, for example, a thermally conductive epoxy material which is white.

A material with heat-dissipating properties can comprise a material including a heat conductive filler. In such embodiments, the material in which the heat conductive filler is included may or may not possess heat-dissipating properties independent of the heat conductive filler. A material in which the heat conductive filler can be included can be readily identified by the skilled artisan.

A material with heat-dissipating properties can comprise, for example, a polymer, resin, or other host material including a heat conductive filler dispersed therein. Such polymers, resins, and other host materials can be readily identified by the skilled artisan.

A material with heat-dissipating properties can comprise, for example, an epoxy material including a heat conductive filler dispersed therein.

In certain embodiments, a material with heat-dissipating properties is electrically insulating.

Other materials with heat-dissipating properties can be identified and used.

A heat conductive filler can comprise, for example, an oxide, a nitride, a titanate, or a mixture including any one or more of the foregoing.

A heat conductive filler can comprise, for example, aluminum oxide, magnesium oxide, silicon oxide, zinc oxide, titanium oxide, or a mixture including any one or more of the foregoing.

A heat conductive filler can comprise, for example, zirconium nitride, boron nitride, aluminum nitride, silicon nitride, or a mixture including any one or more of the foregoing.

A heat conductive filler can comprise, for example, barium titanate, barium strontium titanate, lead zirconium titanate, silicon, or a mixture including any one or more of the foregoing.

Other heat conductive fillers can be identified and used.

A layer comprising a material with heat-dissipating properties can have a thickness of, for example, but not limited to, 5 mm or less, 4 mm or less, 3 mm or less, 2 mm or less, 1 mm or less, 0.8 mm or less, 0.5 mm or less, 0.4 mm or less, 0.3 mm or less, 0.2 mm or less, 0.1 mm or less, 10 microns or less, 1 micron or less, 0.1 micron or less, 50 nm or less. Other thickness may also be determined to be desirable.

A device can include a layer comprising material with heat-dissipating properties that covers at least the top surface of the underlying device.

A device can include a layer comprising material with heat-dissipating properties that covers at least the top surface of the underlying device and can further comprise an edge seal around any exposed sides of the device such that the edge seal and the material with heat-dissipating properties fully encapsulate the outer surfaces of the device disposed over the substrate

Optionally, the layer comprising a material with heat-dissipating properties can also be disposed over external surfaces of the substrate.

Any contacts for the device that may be located on the substrate surface adjacent the device are preferably not covered by the layer.

Optionally, a bead of sealant can be added around the perimeter edge of the encapsulating layer on the substrate to improve the seal.

A device can include a layer comprising a material with heat-dissipating properties that fully encapsulates the outer surfaces of the device disposed over the substrate.

A device can comprise a stacked arrangement of layers of device materials. Each layer can comprise one or more sublayers. Each layer or sublayer can comprise one or more device materials.

A device can comprise a light-emitting device and the nanoparticles can comprise nanoparticles having light-emissive capabilities.

A device can comprise a photovoltaic device.

In accordance with another aspect of the present invention, there is provided a display comprising one or more light-emitting devices taught herein.

In accordance with another aspect of the present invention, there is provided a method for improving the performance of a device, the method comprising providing a layer comprising a material with heat-dissipating properties over an external surface of at least one electrode of the device.

The method can include providing a layer comprising a material with heat-dissipating properties over all surfaces of the top electrode external to the device.

A method can comprise providing a layer comprising a material with heat-dissipating properties over uncovered surfaces of an arrangement of device materials to encapsulate the arrangement from ambient atmosphere.

In a device that includes a substrate as an external surface thereof, the method can include providing a layer comprising a material with heat-dissipating properties over all external surfaces of the device that are not covered by the substrate.

Optionally, the layer can also cover the external substrate surfaces.

Any contacts for the device that may be located on the substrate surface adjacent the device are preferably not covered by the layer.

Optionally, a bead of sealant can be added around the perimeter edge of the encapsulating layer on the substrate to improve the seal.

The method can include providing a layer comprising a material with heat-dissipating properties over all external surfaces of the device.

An encapsulated device is preferably configured to provide an external electrical connection to the device.

The method can further comprise including an interleave layer over an external surface of at least one electrode of the device prior to providing the layer comprising a material with heat-dissipating properties.

An interleave layer can comprise an interleave layer as described above and elsewhere herein.

The method can further comprise including a barrier layer over exposed surfaces of the arrangement of device layers before an interleave layer is disposed over the top layer of the device layers (if included) and before inclusion of the layer comprising a material capable of dissipating heat over at least a portion of the underlying device.

A barrier layer comprises a layer that inhibits, and preferably prevents, passage of at least oxygen and/or water moisture.

Preferably, the barrier layer inhibits, and preferably prevents, passage of at least both oxygen and water moisture.

A barrier layer can comprise a barrier layer as described above and elsewhere herein.

A barrier layer can comprise one or more barrier layers.

A barrier layer preferably covers exposed surfaces of the arrangement of device layers.

A barrier layer is preferably included before an interleave layer is disposed over the top layer of the device layers (if included) and before inclusion of the layer comprising a material capable of dissipating heat over at least a portion of the underlying device.

A method can further comprise including an interleave layer and a barrier layer.

In certain embodiments, a layer can acts as both an interleave layer and a barrier layer.

In certain embodiments, an interleave layer and a barrier layer are separate layers.

In methods which include providing an interleave layer and a barrier layer as separate layers, the barrier layer is preferably included so as to be between a top layer of the arrangement of device layers and the interleave layer.

In certain embodiments, a material with heat-dissipating properties is electrically insulating.

A material with heat-dissipating properties can comprise a material with heat-dissipating properties described above and elsewhere herein.

A layer comprising a material with heat-dissipating properties can be formed at a thickness of, for example, but not limited to, 5 mm or less, 4 mm or less, 3 mm or less, 2 mm or less, 1 mm or less, 0.8 mm or less, 0.5 mm or less, 0.4 mm or less, 0.3 mm or less, 0.2 mm or less, 0.1 mm or less, 10 microns or less, 1 micron or less, 0.1 micron or less, 50 nm or less. Other thickness may also be determined to be desirable.

In accordance with another aspect of the present invention, there is provided a method for improving the performance of a device, the method comprising providing an interleave layer over an external surface of at least one electrode of the device, and providing a layer comprising with heat-dissipating properties over the interleave layer.

An interleave layer can comprise an interleave layer described above and elsewhere herein. An interleave layer can be formed at a thickness, for example, but not limited to, of 500 nm or less, of 400 nm or less, of 300 nm or less, of 200 nm or less, of 100 nm or less, of 50 nm or less, or 25 nm or less, of 20 nm or less, of 10 nm of less, of 5 nm or less, etc. Other thickness may also be determined to be desirable.

An interleave layer can be formed at a thickness of a monolayer of the material from which it is formed.

An interleave layer can be formed as an unpatterned layer.

An interleave layer can be formed as a patterned layer. A pattern can be regular or random.

Optionally, the method further comprises forming a barrier layer over exposed surfaces of the device before the interleave layer is provided.

A barrier layer comprises a layer that inhibits, and preferably prevents, passage of at least oxygen and/or water moisture.

Preferably, the barrier layer inhibits, and preferably prevents, passage of at least both oxygen and water moisture.

A barrier layer can comprise a barrier layer as described above and elsewhere herein.

A barrier layer can comprise one or more barrier layers.

A barrier layer preferably covers exposed surfaces of the arrangement of device layers.

A barrier layer can preferably have a thickness <1 micron. A thickness less than or equal to 50 nm can be preferable. However, as the skilled artisan can appreciate, other thickness can be used taking into consideration other aspects of the device structure, materials, and layer or component sizes, thicknesses, etc.

Examples of materials for inclusion a barrier layer include, but are not limited to, a polymer with oxygen and/or water barrier properties, metal oxide, glass, ceramic, alumina. Such layers can be formed by known techniques. As the skilled artisan will appreciate, other materials with oxygen and/or moisture barrier properties can be identified for inclusion in a barrier layer.

A barrier layer preferably covers exposed surfaces of the arrangement of device layers.

In certain embodiments, a layer can acts as both an interleave layer and a barrier layer.

In certain embodiments, an interleave layer and a barrier layer are separate layers.

A material with heat-dissipating properties can comprise a material with heat-dissipating properties described above and elsewhere herein.

A layer comprising a material with heat-dissipating properties can be formed at a thickness of, for example, but not limited to, 5 mm or less, 4 mm or less, 3 mm or less, 2 mm or less, 1 mm or less, 0.8 mm or less, 0.5 mm or less, 0.4 mm or less, 0.3 mm or less, 0.2 mm or less, 0.1 mm or less, 10 microns or less, 1 micron or less, 0.1 micron or less, 50 nm or less. Other thickness may also be determined to be desirable.

The method can include providing a layer comprising a material with heat-dissipating properties over all surfaces of the top electrode external to the device.

In a device that includes a substrate as an external surface thereof, the method can include providing a layer comprising a material with heat-dissipating properties over all external surfaces of the device that are not covered by the substrate.

Optionally, the layer can also cover the external substrate surfaces.

Any contacts for the device that may be located on the substrate surface adjacent the device are preferably not covered by the layer.

Optionally, a bead of sealant can be added around the perimeter edge of the encapsulating layer on the substrate to improve the seal.

The method can include providing a layer comprising a material with heat-dissipating properties over all external surfaces of the device.

A method can comprise providing a layer comprising a material with heat-dissipating properties over uncovered surfaces of an arrangement of device materials to encapsulate the arrangement from ambient atmosphere.

An encapsulated device is preferably configured to provide an external electrical connection to the device.

A device prepared in accordance with the present invention may exhibit improved peak luminances and/or improved power efficiencies.

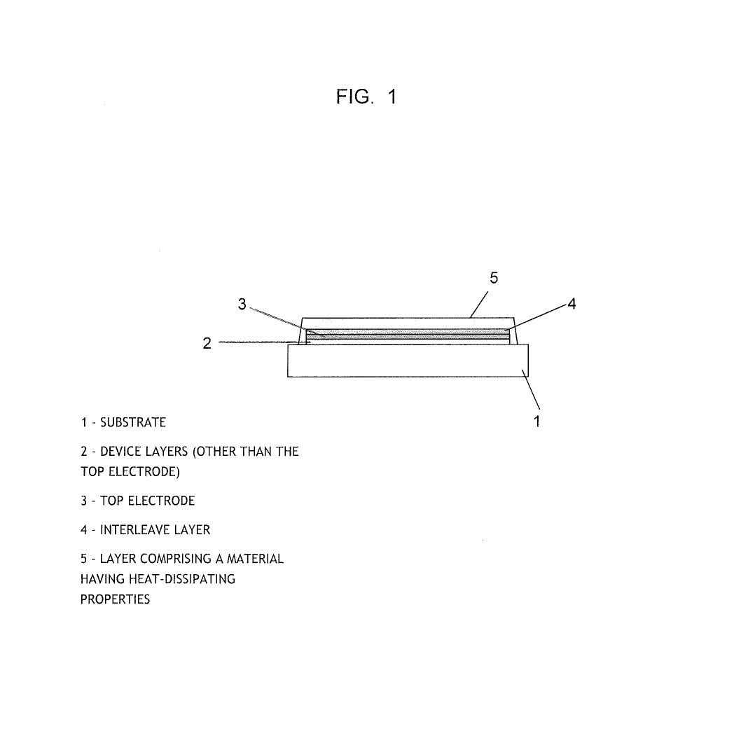

FIG. 1 depicts an example of an embodiment of a device in accordance with one aspect of the present invention in cross-section.

The depicted device example includes a substrate 1. A substrate can be opaque or transparent. A transparent substrate can be used, for example, in the manufacture of a transparent light emitting device. See, for example, Bulovic, V. et al., Nature 1996, 380, 29; and Gu, G. et al., Appl. Phys. Lett. 1996, 68, 2606-2608, each of which is incorporated by reference in its entirety. The substrate can be rigid or flexible. Examples of substrate materials include, without limitation, glass, plastic, metal, insulated metal foil, semiconductor wafer, etc. The substrate can be a substrate commonly used in the art. Preferably the substrate has a smooth surface. A substrate surface free of defects is particularly desirable.

Thickness of the substrate can be selected by the skilled artisan taking into account, e.g., the type of device, the device structure, size, device materials, and intended end use application. Examples of thickness include for example, but are not limited to 5 mm or less, 4 mm or less, 3 mm or less, 2 mm or less, 1 mm or less, 0.8 mm or less, 0.5 mm or less, 0.4 mm or less, 0.3 mm or less, 0.2 mm or less, 0.1 mm or less, 10 microns or less, 1 micron or less, 0.1 micron or less, 50 nm or less. Other thickness may also be determined to be desirable.

Substrates including patterned ITO are commercially available and can be used in making a device according to the present invention.

Device layers (e.g., a first electrode, an active layer (light emissive, light absorbing, second electrode, etc.), and other optional device layers) are disposed over the substrate. (In FIG. 1, device layers (excluding the top electrode) are collectively identified by reference numeral 2, and the top device electrode is identified by reference numeral 3.) The particular device layers, materials included in each of the device layers, and the device structure are selected based on the type of device desired. For example, the materials and structures for various organic light emitting devices, photovoltaic devices, and other light emitting devices can be readily determined by one of ordinary skill in the relevant art. Such selection of materials and structure, and preparation thereof, can be readily carried out by one of ordinary skill in the relevant art.

An example of a device comprising a light-emitting device can include a first electrode disposed over a substrate, a second electrode disposed over the first electrode, and an emissive material between the two electrodes.

The emissive material can comprise quantum confined semiconductor nanoparticles.

The emissive material can comprise nano-phosphors.

The emissive material can comprise an organic electroluminescent materials.

The emissive material can comprise one or more layers.

A layer including an emissive material comprising, for example, a plurality of quantum confined semiconductor nanoparticles (e.g., semiconductor nanocrystals) can be a monolayer of semiconductor nanocrystals. Other thicknesses can also be used.

The emissive material can be patterned or unpatterned.

One electrode can be, for example, an anode comprising a high work function (e.g., greater than 4.0 eV) hole-injecting conductor, such as an indium tin oxide (ITO) layer. Other anode materials include other high work function hole-injection conductors including, but not limited to, for example, tungsten, nickel, cobalt, platinum, palladium and their alloys, gallium indium tin oxide, zinc indium tin oxide, titanium nitride, polyaniline, or other high work function hole-injection conducting polymers. An electrode can be light transmissive or transparent. In addition to ITO, examples of other light-transmissive electrode materials include conducting polymers, and other metal oxides, low or high work function metals, conducting epoxy resins, or carbon nanotubes/polymer blends or hybrids that are at least partially light transmissive. An example of a conducting polymer that can be used as an electrode material is poly(ethlyendioxythiophene), sold by Bayer AG under the trade mark PEDOT. Other molecularly altered poly(thiophenes) are also conducting and could be used, as well as emaraldine salt form of polyaniline.

The other electrode can be, for example, a cathode comprising a low work function (e.g., less than 4.0 eV), electron-injecting, metal, such as Al, Ba, Yb, Ca, a lithium-aluminum alloy (Li:Al), a magnesium-silver alloy (Mg:Ag), or lithium fluoride-aluminum (LiF:A1). Other examples of cathode materials include silver, gold, ITO, etc. An electrode, such as Mg:Ag, can optionally be covered with an opaque protective metal layer, for example, a layer of Ag for protecting the cathode layer from atmospheric oxidation, or a relatively thin layer of substantially transparent ITO. An electrode can be sandwiched, sputtered, or evaporated onto the exposed surface of the solid layer.

One or both of the electrodes can be patterned.

The electrodes of the device can be connected to a voltage source by electrically conductive pathways. In certain aspects and embodiments of the inventions described herein, the substrate, electrode (e.g., anode or cathode) materials and other materials included in a device are selected based on light transparency characteristics. For example, a device comprising a light-emitting device, such selection can enable preparation of a device that emits light from the top surface thereof. A top emitting device can be advantageous for constructing an active matrix device (e.g., a display). In another example, such selection can enable preparation of a device that emits light from the bottom surface thereof. In yet another example, such selection can enable preparation of a device that is transparent on both sides (e.g., fully transparent). Preferably an emitting side is at least 20% transparent. As the skilled artisan will appreciate, higher transparency can be more preferable.

In a light-emitting device, electroluminescence can be produced by the emissive material included in the device when a voltage of proper polarity is applied across the heterostructure.

A light-emitting device can further include one or more charge transport layers (which can be organic or inorganic). Charge transport layers can be positioned between the electrodes.

Charge transport layers comprising organic materials and other information related to fabrication of organic charge transport layers are discussed in more detail in U.S. patent application Ser. Nos. 11/253,612 for “Method And System For Transferring A Patterned Material”, filed 21 Oct. 2005, and 11/253,595 for “Light Emitting Device Including Semiconductor Nanocrystals”, filed 21 Oct. 2005. The foregoing patent applications are hereby incorporated herein by reference in its entirety.

Organic charge transport layers may be disposed by known methods such as a vacuum vapor deposition method, a sputtering method, a dip-coating method, a spin-coating method, a casting method, a bar-coating method, a roll-coating method, and other film deposition methods. Preferably, organic layers are deposited under ultra-high vacuum (e.g., ≦10⁻⁸ torr), high vacuum (e.g., from about 10⁻⁸ torr to about 10⁻⁵ torr), or low vacuum conditions (e.g., from about 10⁻⁵ torr to about 10⁻³ torr). In certain embodiments, the organic layers are deposited at high vacuum conditions from about 1×10⁻⁷ to about 5×10⁻⁶ torr. Alternatively, organic layers may be formed by multi-layer coating while appropriately selecting solvent for each layer.

Charge transport layers including inorganic materials and other information related to fabrication of inorganic charge transport layers are discussed further below and in more detail in U.S. Patent Application No. 60/653,094 for “Light Emitting Device Including Semiconductor Nanocrystals”, filed 16 Feb. 2005 and U.S. patent application Ser. No. 11/354,185, filed 15 Feb. 2006, the disclosures of each of which are hereby incorporated herein by reference in their entireties.

Charge transport layers comprising an inorganic semiconductor can be deposited at a low temperature, for example, by a known method, such as a vacuum vapor deposition method, an ion-plating method, sputtering, inkjet printing, sol-gel techniques, other solution base techniques (e.g., spin coating, etc.), etc.

In some applications, the substrate can further include a backplane. A backplane can include active or passive electronics for controlling or switching power to individual pixels or light-emitting devices. Including a backplane can be useful for applications such as displays, sensors, or imagers. In particular, the backplane can be configured as an active matrix, passive matrix, fixed format, direct drive, or hybrid. The display can be configured for still images, moving images, or lighting. A display including an array of light emitting devices can provide white light, monochrome light, or color-tunable light.

In addition to the charge transport layers, a device may optionally further include one or more charge-injection layers, e.g., a hole-injection layer (either as a separate layer or as part of the hole transport layer) and/or an electron-injection layer (either as a separate layer as part of the electron transport layer). Charge injection layers comprising organic materials can be intrinsic (un-doped) or doped.

One or more charge blocking layers may still further optionally be included. For example, an electron blocking layer (EBL), a hole blocking layer (HBL), or an exciton blocking layer (eBL), can be introduced in the structure. A blocking layer can include, for example, 3-(4-biphenylyl)-4-phenyl-5-tert butylphenyl-1,2,4-triazole (TAZ), 3,4,5-triphenyl-1,2,4-triazole, 3,5-bis(4-test-butylphenyl)-4-phenyl-1,2,4-triazole, bathocuproine (BCP), 4,4′,4″-tris{N-(3-methylphenyl)-N-phenylamino}triphenylamine (m-MTDATA), polyethylene dioxythiophene (PEDOT), 1,3-bis(5-(4-diphenylamino)phenyl-1,3,4-oxadiazol-2-yl)benzene, 2-(4-biphenylyl)-5-(4-tertbutylphenyl)-1,3,4-oxadiazole, 1,3-bis[5-(4-(1,1-dimethylethyl)phenyl)-1,3,4-oxadiazol-5,2-yl)benzene, 1,4-bis(5-(4-diphenylamino)phenyl-1,3,4-oxadiazol-2-yl)benzene, 1,3,5-tris[5-(4-(1,1-dimethylethyl)phenyl)-1,3,4-oxadiazol-2-yl)benzene, or 2,2′,2″-(1,3,5-Benzinetriyl)-tris(1-phenyl-1-H-benzimidazole) (TPBi).

Charge blocking layers comprising organic materials can be intrinsic (un-doped) or doped.

Charge injection layers (if any), and charge blocking layers (if any) can be deposited by spin coating, dip coating, vapor deposition, or other thin film deposition methods. See, for example, M. C. Schlamp, et al., J. Appl. Phys., 82, 5837-5842, (1997); V. Santhanam, et al., Langmuir, 19, 7881-7887, (2003); and X. Lin, et al., J. Phys. Chem. B, 105, 3353-3357, (2001), each of which is incorporated by reference in its entirety.

Other multilayer structures may optionally be used (see, for example, U.S. patent application Ser. Nos. 10/400,907 and 10/400,908, filed Mar. 28, 2003, each of which is incorporated by reference in its entirety).

A light-emitting device including an emissive material comprising a plurality of quantum confined semiconductor nanoparticles (e.g., semiconductor nanocrystals) is typically processed in a controlled (oxygen-free and moisture-free) environment.

Examples of light emitting devices including an emissive layer comprising quantum confined semiconductor nanoparticles are described in International Application No. PCT/US2009/002123, filed 3 Apr. 2009, by QD Vision, Inc., et al, entitled “Light-Emitting Device Including Quantum Dots”, which published as WO2009/123763 on 8 Oct. 2009, and WO2011/005859, published 13 Jan. 2011, entitled “Stable And All Solution Processable Quantum Dot Light-Emitting Diodes”, of University of Florida Research Foundation, Inc. Each of the foregoing patent publications is hereby incorporated herein by reference in its entirely.

Other materials, techniques, methods, applications, and information that may be useful with the present invention are described in: International Application No. PCT/US2007/013152, filed Jun. 4, 2007, of Coe-Sullivan, et al., for “Light-Emitting Devices And Displays With Improved Performance”; U.S. Application No. 61/262,501 of Kazlas, et al., filed 18 Nov. 2009, entitled “Light-Emitting Device Including Quantum Dots”, International Application No. PCT/US2009/002789, filed 6 May 2009, by QD Vision, Inc., et al, entitled “Solid State Light Devices Including Quantum Confined Semiconductor Nanoparticles”, which published as WO 2009/151515 on 17 Dec. 2009, WO2004/099664 published 18 Nov. 2004, and International Application No. PCT/US2008/013504, filed Dec. 8, 2008, entitled “Flexible Devices Including Semiconductor Nanocrystals, Arrays, and Methods”, of Kazlas, et al., which published as WO2009/099425 on Aug. 13, 2009, each of the foregoing being hereby incorporated herein by reference in its entirety.

In FIG. 1, interleave layer 4 can optionally be included prior to the addition of the layer comprising a material with heat-dissipating properties 5.

As shown in the depicted example, the layer comprising a material with heat-dissipating properties 5 fully encapsulates external surfaces of the layers of the device that are not covered by the substrate.

An encapsulated device described herein is preferably configured to provide an external electrical connection to the device. Examples of such configurations include, but are not limited to pattern electrodes, vias, etc. Other designs form providing external electrical connection to the device can also be used. Such designs can be selected by the skilled artisan and may be influenced by the device design, device size, device materials, intended end-use application, etc.

Contacts for the device that may be located, for example, on the substrate surface near the device and are preferably not covered by the layer or other materials.

Optionally, a bead of sealant (e.g., UV curable epoxy or other sealant) can be further added around the perimeter of the encapsulated device along the seam where the layer joins the substrate to improve the seal.

Alternatively, the layer comprising a material with heat-dissipating properties 5 can cover the uppermost surface of the device stack, and a separate sealant can be added around the edges of the device stack to fully seal the device.

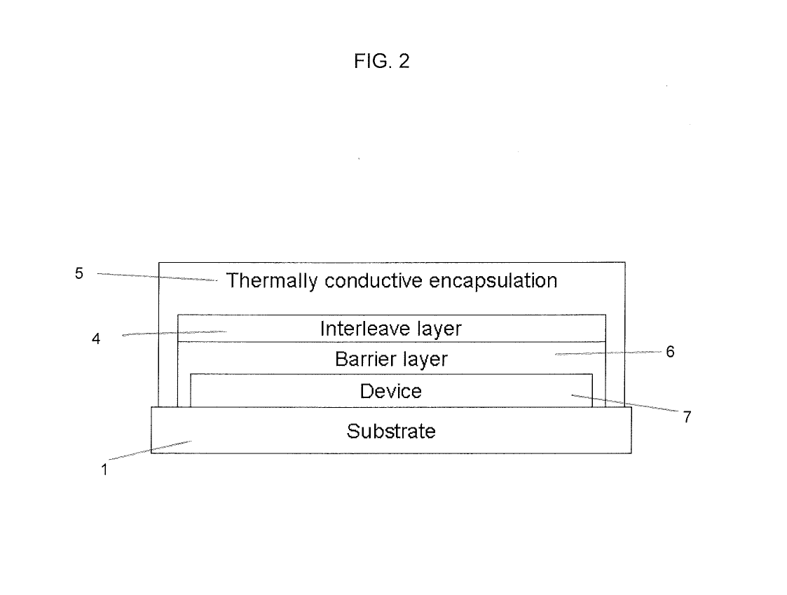

FIG. 2 schematically depicts an example of an embodiment of a device in accordance with one aspect of the present invention in cross-section. The depicted embodiment includes a substrate 1. The substrate can comprise a substrate as described elsewhere herein. A typical substrate can have a thickness in a range from about 0.1 to about 1 mm, although other thicknesses can be used. A device 7 comprising an arrangement of device materials is formed an upper surface of the substrate. The device can comprise a device such as those described herein. In certain embodiments, the device comprises an arrangement of thin films or layers (which may also be referred to herein as a thin film device). For example, a thin film device can have a top-to-bottom thickness (e.g., from bottom device layer to top device layer) no greater than 500 nm. An example of typical thickness can be in a range from about 100 nm to about 300 nm. The depicted embodiment includes a barrier layer 6 described herein. As shown, the barrier layer encapsulates the external surfaces of the device (e.g., the surfaces that are not covered by the substrate). As discussed above, a barrier film can preferably have a thickness <1 micron. In certain embodiments, a barrier film can have a thickness of up to about 150 nm. In certain embodiments, a barrier layer can have a thickness up about 100 nm, for example, but not limited to, a barrier layer can have a thickness in a range from about 2 to about 100 nm, from about 5 nm to about 100 nm, from about 2 nm to about 50 nm, from about 5 nm to about 50 nm, from about 10 nm to about 100 nm, from about 10 nm to about 50 nm. Other barrier layer thickness may also be used as the skilled artisan may determine. As shown, an interleave layer 4 described herein is disposed on the barrier layer. In certain embodiments, the interleave layer can have a thickness from a monolayer to about 50 nm. As shown in FIG. 2, thermally conductive encapsulation is provided by a layer comprising a material with heat dissipating properties 5 as described herein encapsulates the external surfaces of the underlying arrangement including the device, barrier layer and interleave layer disposed on the substrate. As discussed above, the layer comprising a material with heat dissipating properties can, for example, have a thickness of 5 mm or less. In certain embodiments, for example, such layer can have a thickness in a range from about 0.1 to about 1 mm. Other thickness may also be used as the skilled artisan may determine.

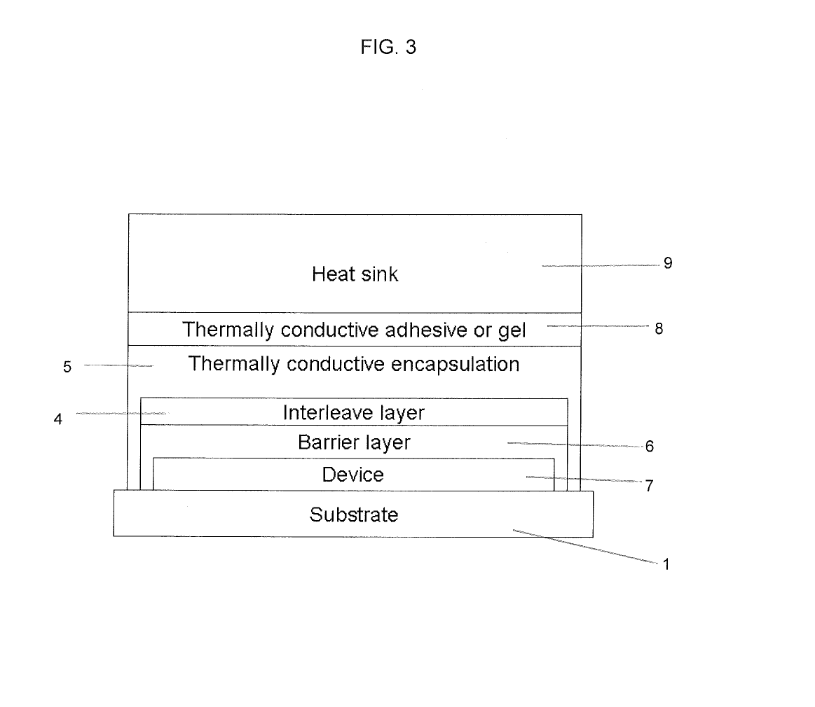

FIG. 3 schematically depicts an example of an embodiment of a device in accordance with one aspect of the present invention further including a heat sink attached thereto. The example depicted in FIG. 3 shows an embodiment of device as shown in FIG. 2 that further includes a heat sink attached to the layer comprising a material with heat dissipating properties. As shown, the heat sink 9 is attached by a thermally conductive adhesive or gel 8. Other known attachment techniques can also be used.

In the examples of the embodiments depicted in FIGS. 1-3, the various layers are in contact with each other.

The present invention will be further clarified by the following non-limiting example(s), which is intended to be exemplary of the present invention.

### Example

Following is an example of a method for applying a layer comprising a material having heat-dissipating properties to a completed device.

Equal parts of a 2-part epoxy, part number EP37-3FLFAO, available from Master Bond, Inc. 154 Hobart Street, Hackensack, N.J. 07601 USA, is mixed by gentle stirring to avoid bubble formation.

The mixed epoxy is degassed before use, (e.g., if bubbles are visible. Degassing can be carried out by placing the mixed epoxy into plastic vacuum reservoir (desiccator) with pump on. The mixed epoxy can be pumped, for example, for 2 to 5 minutes. This is repeated until no bubbles are visible.

An amount of the degassed mixed epoxy is dispensed onto the top surface of the aluminum electrode of the device to be coated. (The amount of mixed epoxy dispensed is selected to be sufficient to cover at least the top surface of the completed device.) The dispensed epoxy mixture is blade coated across the top surface of the completed device to form a substantially uniform coating. (Any contacts that may be located on the substrate surface adjacent the device can be masked during coating and cleaned as necessary with a small swab soaked with methanol.)

The blade coated device is then put into a vacuum oven preset at 65° C. and purged with N₂ while the vacuum pump is turned so that the vacuum with N₂ flow is balanced for the vacuum with −10 inches Hg. The device is then baked at 65° C. for 17 hours.

After baking/thermal curing of the mixed epoxy is completed, the device is stored in a dry box for any further processing that may be desired.

Optionally, an added step would be to add a thin bead of encapsulate (UV curable epoxy) around the edges of the cured mixed epoxy layer to provide a better seal.

Nanoparticles that can be included in a device layer can comprise quantum confined semiconductor nanoparticles (including, e.g., semiconductor nanocrystals) which are nanometer-scale inorganic semiconductor nanoparticles. Semiconductor nanocrystals include, for example, inorganic crystallites between about 1 nm and about 1000 nm in diameter, preferably between about 2 nm and about 50 um, more preferably about 1 nm to about 20 nm (such as about 6, 7, 8, 9, 10, 11, 12, 13, 14, 15, 16, 17, 18, 19, or 20 nm).

Semiconductor nanocrystals can have an average nanocrystal diameter less than about 150 Angstroms (Å). Semiconductor nanocrystals having an average nanocrystal diameter in a range from about 12 to about 150 Å can be particularly desirable.

However, depending upon the composition and desired emission wavelength of the semiconductor nanocrystal, the average diameter may be outside of these various preferred size ranges.

The semiconductor forming the nanoparticles and nanocrystals can comprise Group IV elements, Group II-VI compounds, Group II-V compounds, Group III-VI compounds, Group III-V compounds, Group IV-VI compounds, Group I-III-VI compounds, Group II-IV-VI compounds, or Group II-IV-V compounds, for example, CdS, CdO, CdSe, CdTe, ZnS, ZnO, ZnSe, ZnTe, MgTe, GaAs, GaP, GaSb, GaN, HgS, HgO, HgSe, HgTe, InAs, InP, InSb, InN, AlAs, AlP, AISb, AIS, PbS, PbO, PbSe, Ge, Si, alloys thereof, and/or mixtures thereof, including ternary and quaternary mixtures and/or alloys.

Examples of the shape of the nanoparticles and nanocrystals include sphere, rod, disk, other shape or mixtures thereof.

Quantum confined semiconductor nanoparticles (including, e.g., semiconductor nanocrystals) can include a “core” of one or more first semiconductor materials, and may further include an overcoating or “shell” of a second semiconductor material on at least a portion of a surface of the core. The shell can surround the core. A quantum confined semiconductor nanoparticle (including, e.g., semiconductor nanocrystal) core including a shell on at least a portion of a surface of the core is also referred to as a “core/shell” semiconductor nanocrystal.

For example, a quantum confined semiconductor nanoparticle (including, e.g., semiconductor nanocrystal) can include a core comprising a Group IV element or a compound represented by the formula MX, where M is cadmium, zinc, magnesium, mercury, aluminum, gallium, indium, thallium, or mixtures thereof, and X is oxygen, sulfur, selenium, tellurium, nitrogen, phosphorus, arsenic, antimony, or mixtures thereof. Examples of materials suitable for use as a core include, but are not limited to, CdS, CdO, CdSe, CdTe, ZnS, ZnO, ZnSe, ZnTe, MgTe, GaAs, GaP, GaSb, GaN, HgS, HgO, HgSe, HgTe, InAs, InP, InSb, InN, AlAs, AlP, AlSb, AIS, PbS, PbO, PbSe, Ge, Si, alloys thereof, and/or mixtures thereof, including ternary and quaternary mixtures and/or alloys. Examples of materials suitable for use as a shell include, but are not limited to, CdS, CdO, CdSe, CdTe, ZnS, ZnO, ZnSe, ZnTe, MgTe, GaAs, GaP, GaSb, GaN, HgS, HgO, HgSe, HgTe, InAs, InP, InSb, InN, AlAs, AlP, AISb, AIS, PbS, PbO, PbSe, Ge, Si, alloys thereof, and/or mixtures thereof, including ternary and quaternary mixtures and/or alloys.

A “shell” material can have a bandgap greater than the bandgap of the core material and can be chosen so as to have an atomic spacing close to that of the “core” substrate. The shell material can have a bandgap less than the bandgap of the core material. The shell and core materials can have the same crystal structure. Shell materials are discussed further below. For further examples of core/shell semiconductor structures, see U.S. application Ser. No. 10/638,546, entitled “Semiconductor Nanocrystal Heterostructures”, filed 12 Aug. 2003, which is hereby incorporated herein by reference in its entirety.

Quantum confined semiconductor nanoparticles are preferably members of a population of semiconductor nanoparticles having a narrow size distribution. More preferably, the quantum confined semiconductor nanoparticles (including, e.g., semiconductor nanocrystals) comprise a monodisperse or substantially monodisperse population of nanoparticles.

Quantum confined semiconductor nanoparticles can show strong quantum confinement effects that can be harnessed in designing bottom-up chemical approaches to create optical properties that are tunable with the size and composition of the nanoparticles.

For example, preparation and manipulation of semiconductor nanocrystals are described in Murray et al. (J. Am. Chem. Soc., 115:8706 (1993)); in the thesis of Christopher Murray, “Synthesis and Characterization of II-VI Quantum Dots and Their Assembly into 3-D Quantum Dot Superlattices”, Massachusetts Institute of Technology, September, 1995; and in U.S. patent application Ser. No. 08/969,302 entitled “Highly Luminescent Color-selective Materials” which are hereby incorporated herein by reference in their entireties.

Quantum confined semiconductor nanoparticles (including, but not limited to, semiconductor nanocrystals) optionally have ligands attached thereto.

Examples of ligands include alkyl phosphines, alkyl phosphine oxides, alkyl phosphonic acids, or alkyl phosphinic acids, pyridines, furans, and amines. More specific examples include, but are not limited to, pyridine, tri-n-octyl phosphine (TOP), tri-n-octyl phosphine oxide (TOPO) and tris-hydroxylpropylphosphine (tHPP), and 3,5-di-tert-butyl-4-hydroxybenzylphosphonic acid. Technical grade TOPO can be used.

Ligands can be derived from the coordinating solvent used during the growth process. The surface can be modified by repeated exposure to an excess of a competing coordinating group to form an overlayer. For example, a dispersion of the capped semiconductor nanocrystal can be treated with a coordinating organic compound, such as pyridine, to produce crystallites which disperse readily in pyridine, methanol, and aromatics but no longer disperse in aliphatic solvents. Such a surface exchange process can be carried out with any compound capable of coordinating to or bonding with the outer surface of the semiconductor nanocrystal, including, for example, phosphines, thiols, amines and phosphates. The semiconductor nanocrystal can be exposed to short chain polymers which exhibit an affinity for the surface and which terminate in a moiety having an affinity for a suspension or dispersion medium. Such affinity improves the stability of the suspension and discourages flocculation of the semiconductor nanocrystal. Semiconductor nanocrystals can alternatively be prepared with use of non-coordinating solvent(s).

A suitable coordinating ligand can be purchased commercially or prepared by ordinary synthetic organic techniques.

When an electron and hole localize on a quantum confined semiconductor nanoparticle (including, but not limited to, a semiconductor nanocrystal), emission can occur at an emission wavelength. The emission has a frequency that corresponds to the band gap of the quantum confined semiconductor material. The band gap is a function of the size of the nanoparticle. Quantum confined semiconductor nanoparticle s having small diameters can have properties intermediate between molecular and bulk forms of matter. For example, quantum confined semiconductor nanoparticles having small diameters can exhibit quantum confinement of both the electron and hole in all three dimensions, which leads to an increase in the effective band gap of the material with decreasing crystallite size. Consequently, for example, both the optical absorption and emission of semiconductor nanocrystals shift to the blue, or to higher energies, as the size of the crystallites decreases.

For an example of blue light-emitting semiconductor nanocrystal materials, see U.S. patent application Ser. No. 11/071,244, filed 4 Mar. 2005, which is hereby incorporated by reference herein in its entirety.

The emission from a quantum confined semiconductor nanoparticle can be a narrow Gaussian emission band that can be tuned through the complete wavelength range of the ultraviolet, visible, or infra-red regions of the spectrum by varying the size of the quantum confined semiconductor nanoparticle, the composition of the quantum confined semiconductor nanoparticle, or both. For example, CdSe can be tuned in the visible region and InAs can be tuned in the infra-red region. The narrow size distribution of a population of quantum confined semiconductor nanoparticles can result in emission of light in a narrow spectral range. The population can be monodisperse preferably exhibits less than a 15% rms (root-mean-square) deviation in diameter of the quantum confined semiconductor nanoparticle s, more preferably less than 10%, most preferably less than 5%. Spectral emissions in a narrow range of no greater than about 75 nm, preferably 60 nm, more preferably 40 nm, and most preferably 30 nm full width at half max (FWHM) for quantum confined semiconductor nanoparticle s that emit in the visible can be observed. IR-emitting quantum confined semiconductor nanoparticle s can have a FWHM of no greater than 150 nm, or no greater than 100 nm. The breadth of the emission decreases as the dispersity of quantum confined semiconductor nanoparticle diameters decreases.

For example, semiconductor nanocrystals can have high emission quantum efficiencies such as greater than 10%, 20%, 30%, 40%, 50%, 60%, 70%, 80%, or 90%.

The narrow FWHM of semiconductor nanocrystals can result in saturated color emission. The broadly tunable, saturated color emission over the entire visible spectrum of a single material system is unmatched by any class of organic chromophores (see, for example, Dabbousi et al., J. Phys. Chem. 101, 9463 (1997), which is incorporated by reference in its entirety). A monodisperse population of semiconductor nanocrystals will emit light spanning a narrow range of wavelengths. A pattern including more than one size of semiconductor nanocrystal can emit light in more than one narrow range of wavelengths. The color of emitted light perceived by a viewer can be controlled by selecting appropriate combinations of semiconductor nanocrystal sizes and materials. The degeneracy of the band edge energy levels of semiconductor nanocrystals facilitates capture and radiative recombination of all possible excitons.

Transmission electron microscopy (TEM) can provide information about the size, shape, and distribution of the semiconductor nanocrystal population. Powder X-ray diffraction (XRD) patterns can provide the most complete information regarding the type and quality of the crystal structure of the semiconductor nanocrystals. Estimates of size are also possible since particle diameter is inversely related, via the X-ray coherence length, to the peak width. For example, the diameter of the semiconductor nanocrystal can be measured directly by transmission electron microscopy or estimated from X-ray diffraction data using, for example, the Scherrer equation. It also can be estimated from the UV/Vis absorption spectrum.

As discussed above, nanoparticles that can be included in a device layer can comprise nano-phosphors. Nano-phosphors are known in the art. See, for example, U.S. Pat. No. 5,882,779 of Lawandy for “Semiconductor Nanocrystal Materials and Display Apparatus Employing Same”, issued on 16 Mar. 1999 which is hereby incorporated herein by reference in its entirety.

As used herein, “top”, “bottom”, “over”, and “under” are relative positional terms, based upon a location from a reference point. More particularly, “top” means farthest away from a reference point, while “bottom” means closest to the reference point. Where, e.g., a layer is described as disposed or deposited “over” a component or substrate, there may be other layers between the layer and component or substrate. As used herein, “cover” is also a relative position term, based upon a location from a reference point. For example, where a first material is described as covering a second material, the first material is disposed over, but not necessarily in contact with the second material.

As used herein, the singular forms “a”, “an” and “the” include plural unless the context clearly dictates otherwise. Thus, for example, reference to an emissive material includes reference to one or more of such materials.

Applicants specifically incorporate the entire contents of all cited references in this disclosure. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

1-40. (canceled)

41. A device comprising a substrate, an arrangement of device materials including a first electrode disposed over a predetermined region of a surface of the substrate, an active layer disposed over the first electrode, wherein the active layer comprises quantum-confined semiconductor nanoparticles having light-absorbing and/or light-emissive capabilities, a second electrode disposed over the active layer, and a layer comprising a material with heat-dissipating properties disposed over the second electrode.

42. (canceled)

43. (canceled)

44. A device in accordance with claim 41 further comprising an interleave layer between the second electrode and the layer comprising a material with heat-dissipating properties.

45. A device in accordance with claim 44 wherein the interleave layer comprises a material with a lower surface energy than that of the device material on which it is disposed.

46. A device in accordance with claim 45 wherein the interleave layer has a thickness of 500 nm or less.

47. A device in accordance with claim 41 wherein the material with heat-dissipating properties comprises a material including a heat conductive filler.

48. A device in accordance with claim 41 wherein the material with heat-dissipating properties comprises a thermally conductive epoxy material.

49. A device in accordance with claim 41 wherein the material with heat-dissipating properties comprises an epoxy material including a heat conductive filler dispersed therein.

50. A device in accordance with claim 47 wherein the heat conductive filler comprises an oxide, a nitride, a titanate, or a mixture including any one or more of the foregoing.

51. A device in accordance with claim 41 wherein the material with heat-dissipating properties covers at least the top surface of the uppermost underlying device material and the device further comprises an edge seal around any exposed sides of the device such that the edge seal and the material with heat-dissipating properties fully encapsulate the arrangement of device materials.

52. A device in accordance with claim 41 wherein the material with heat-dissipating properties fully encapsulates the underlying arrangement of device materials that is disposed over the substrate.

53. A device in accordance with claim 41 further comprising a barrier layer between the second electrode and the layer comprising a material with heat-dissipating properties.

54. A device in accordance with claim 44 further comprising a barrier layer between the second electrode and the interleave layer.

55. A device in accordance with claim 53 wherein the barrier layer covers the outer surfaces of the underlying arrangement of device materials that is disposed over the substrate.

56. A device in accordance with claim 53 wherein the barrier layer comprises a layer that inhibits passage of at least oxygen and/or water.

57. A device in accordance with claim 53 wherein the barrier layer has a thickness less than 500 nm.

58. A device in accordance with claim 53 wherein the barrier layer has a thickness in a range from about 5 nm to about 150 nm.

59. A device in accordance with claim 41 wherein the layer comprising a material with heat-dissipating properties has a thickness less than 5 mm.

60. A device in accordance with claim 41 wherein the layer comprising a material with heat-dissipating properties has a thickness in a range from about 0.1 to 1 mm.

61. A device in accordance with claim 41 wherein the arrangement of device materials has a thickness no greater than 500 nm.

62. A device in accordance with claim 41 wherein the arrangement of device materials has a thickness no greater than 300 nm.

63. A device in accordance with claim 41 wherein the layer comprising a material with heat-dissipating properties has a thickness that is greater than the thickness of the arrangement of device materials.

64-70. (canceled)

71. A device in accordance with claim 44 wherein the interleave layer is in contact with the uppermost surface of the arrangement of device materials.

72. A device in accordance with claim 54 wherein the interleave layer is in contact with the barrier layer disposed on the uppermost surface of the arrangement of device materials.

73. A device in accordance with claim 71 wherein the layer comprising a material with heat-dissipating properties is in contact with the interleave layer.

74. A device in accordance with claim 72 wherein the layer comprising a material with heat-dissipating properties is in contact with the interleave layer.

75. A device in accordance with claim 41 wherein there is no air separation between layers in the device.

76-81. (canceled)

82. A device in accordance with claim 41 further comprising a heat sink component attached to an outer surface of the layer comprising a material with heat-dissipating properties.

83. A device in accordance with claim 82 wherein the heat sink component is attached to the outer surface of the layer comprising a material with heat-dissipating properties by a thermally conductive adhesive.

84. (canceled)

85. (canceled)

86. A device in accordance with claim 54 wherein the barrier layer covers the outer surfaces of the underlying arrangement of device materials that is disposed over the substrate.

87. A device in accordance with claim 54 wherein the barrier layer comprises a layer that inhibits passage of at least oxygen and/or water.

88. A device in accordance with claim 54 wherein the barrier layer has a thickness less than 500 nm.

89. A device in accordance with claim 54 wherein the barrier layer has a thickness in a range from about 5 nm to about 150 nm.
